(19) United States
(12) Patent Application Publication
(10) Pub. No.: US 2025/0230329 A1
(43) Pub. Date: Jul. 17, 2025

(54) Quantum Dot Ink, Quantum Dot Layer Patterning Method and Quantum Dot Optoelectronic Device

(71) Applicant: BOE Technology Group Co., Ltd., Beijing (CN)

(72) Inventor: Shaoyong LU, Beijing (CN)

(21) Appl. No.: 18/701,942

(22) PCT Filed: May 12, 2023
(86) PCT No.: PCT/CN2023/093982

§ 371 Date: Apr. 17, 2024

(30) Foreign Application Priority Data
Jun. 21, 2022 (CN) 202210706849.5

(51) Int. Cl. C09D 11/50; C09K 11/88; H10H 29/01; H10H 29/851

(52) U.S. Cl. CPC C09D 11/50; C09K 11/883; H10H 29/0361; H10H 29/8512

(57) ABSTRACT

The present application relates to a quantum dot ink, a quantum dot layer patterning method, and a quantum dot optoelectronic device. The quantum dot ink contains a quantum dot material; a cross-linking agent and a photoacid generator, wherein the quantum dot material comprises quantum dots and an organic ligand on surfaces of the quantum dots, the organic ligand comprises a crosslinking unit and a coordination functional group coordinated with the quantum dots, the crosslinking unit in the organic ligand can be subjected to a cross-linking reaction with a polyhydroxy compound cross-linking agent under the catalysis of hydrogen ions generated via the photoacid generator under ultraviolet irradiation. By means of the quantum dot ink, since photocrosslinking molecules directly participate in patterning of a quantum dot layer, there is no need to wash away a photoresist sacrificial layer compared to existing photoresist patterning methods, so that the process flow is greatly simplified.

### CROSS-REFERENCE TO RELATED APPLICATIONS

The present application is a U.S. National Phase Entry of International Application No. PCT/CN2023/093982, having an international filing date of May 12, 2023, which claims priority to Chinese Patent Application No. 202210706849.5 filed to the CNIPA on Jun. 21, 2022 and entitled “Quantum Dot Ink, Quantum Dot Layer Patterning Method and Quantum Dot Optoelectronic Device”. The entire contents of above-identified applications are hereby incorporated into the present application by reference.

### TECHNICAL FIELD

Embodiments of the present application relate to, but are not limited to, the technical field of quantum dot patterning, and in particular to a quantum dot ink, a method for patterning quantum dot layer, and a quantum dot optoelectronic device.

### BACKGROUND

Colloidal nanocrystals are nano-sized inorganic nanoparticles synthesized in solution, and their surfaces are usually coated with ligands, thus providing colloidal stability for nanocrystals. Generally, physical and chemical properties such as photoelectromagnetism of nanocrystals are determined by their inorganic cores, and these properties are deeply affected by the composition, size and morphology of the inorganic cores. Surface ligands endow nanocrystals with machinability and facilitate the construction of complex devices. These properties make colloidal nanocrystals an important building block for constructing advanced materials and devices. The potential application of nanomaterials will be brought into full play if the composition, size, morphology, crystal structure and surface properties of nanocrystals are regulated more finely.

According to the classical quantum confinement effect, when the geometric radius of semiconductor nanocrystals is smaller than the exciton Bohr radius of its bulk material, the energy levels of valence band and conduction band will appear discrete distribution, and the properties of nanocrystals will become size-dependent. Semiconductor nanocrystals with a radius size smaller than or close to the exciton Bohr radius are called quantum dots (usually 1-10 nm in size).

Due to the quantum confinement effect, quantum dots have excellent luminescence properties such as wide-band absorption, narrow-band emission and continuously adjustable peak position. As a new generation of luminescent and optoelectronic materials, quantum dots are expected to have a subversive impact on many application fields such as display and illumination, laser, single photon source, and biomedical imaging. Quantum dots have emerged in the field of display, and commercial quantum dot display products have come out.

In many device applications, the performance of colloidal nanocrystals is mainly realized through the integration of device units with multilayer nanocrystal stack structure, and the construction of integrated devices usually requires the patterning of device unit films or arrays. For example, the construction of panchromatic quantum dot display devices depends on the precise patterning of red, green and blue light emitting device units. Therefore, the patterning of colloidal nanocrystals is of great significance to the construction of low-cost, large-area and high-efficiency thin film optoelectronic devices.

At present, facing the optoelectronic application requirements of quantum dots, people have developed a variety of patterning methods, such as an inkjet printing method, a transfer printing method and a lithography method, and the like. These methods have their own advantages and disadvantages. Lithography is expected to become a promising quantum dot patterning technology because of its low cost, easy mass production and high-definition pattern resolution.

### SUMMARY

The following is a summary of subject matters described herein in detail. This summary is not intended to limit the protection scope of the claims.

According to the research of the inventor(s) of the present disclosure on the patterning technology of quantum dots, it is found that the existing photolithography method uses a large amount of photoresist, and a large amount of organic solvent is needed in the patterning process of the quantum dot layer to dissolve the photoresist for coating and developing after exposure, thereby increasing the cost and resulting in environmental problems. Therefore, there is a need to develop a green and environmentally friendly patterning method for quantum dot layer.

In one aspect, an embodiment of the present disclosure provides a quantum dot ink comprising:
(1) a quantum dot material, wherein the quantum dot material comprises quantum dots and an organic ligand on the surfaces of the quantum dots, and the organic ligand comprises a cross-linking unit and a coordination functional group coordinated with the quantum dots;
(2) a cross-linking agent; and
(3) a photoacid generator.

In the embodiment, the cross-linking unit in the organic ligand can undergo a cross-linking reaction with the cross-linking agent under the catalysis of hydrogen ions generated by the photoacid generator under the irradiation of ultraviolet light.

As a second aspect of the embodiments of the present disclosure, the present disclosure further provides a method for patterning a quantum dot layer, the method comprises the following steps:
a. forming a quantum dot layer with the quantum dot ink according to the present disclosure;
b. under the shielding of a mask, exposing the quantum dot layer under the irradiation of ultraviolet light to carry out a cross-linking reaction; and
c. removing the quantum dots in the unexposed region by eluting with a developing solution to obtain the patterned quantum dot layer.

As a third aspect of the embodiments of the present disclosure, the present disclosure further provides a quantum dot layer comprising a plurality of sub-pixels, and a material for each sub-pixel comprises a quantum dot material, the surface of which is linked with a cross-linking product of the organic ligand and the cross-linking agent as described above.

As a fourth aspect of an embodiments of the present disclosure, the present disclosure further provides a quantum dot optoelectronic device comprising the quantum dot layer as described above.

As a fifth aspect of the embodiments of the present disclosure, the present disclosure further provides a method for fabricating a quantum dot optoelectronic device, comprising the step of forming a quantum dot layer using the aforementioned method for patterning of a quantum dot layer.

As a sixth aspect of the embodiments of the present disclosure, the present disclosure further provides a display device comprising a quantum dot light emitting diode comprising the aforementioned quantum dot layer.

Other aspects of the present disclosure may be comprehended after the detailed descriptions are read and understood.

### DETAILED DESCRIPTION

Hereinafter the technical solution provided by the present disclosure will be described in detail by way of embodiments. These embodiments are provided so that the present disclosure will be more comprehensive and complete and the idea of exemplary embodiments will be fully communicated to those skilled in the art. The features, structures, or characteristics described by these exemplary embodiments may be incorporated in one or more embodiments in any suitable manner so as to be capable of being implemented in various forms, and therefore should not be construed as being limited to the embodiments set forth herein. Apparently, the described embodiments are a part of the embodiments of the present disclosure, not all of the embodiments. The embodiments of the present disclosure and features in the embodiments may be combined to each other to obtain new embodiments if there is no conflict. All other embodiments obtained by those of ordinary skill in the art based on the embodiments provided by the present disclosure fall within the scope of protection of the present disclosure.

All technical and scientific terms used herein have the same meanings as understood by those of ordinary skill in the art to which the present disclosure pertains, unless otherwise defined. In case of conflict, this specification (including definitions) shall prevail.

The term “first”, “second” and similar terms used in the present disclosure do not indicate any order, quantity, or importance, but are used only for distinguishing different components. The term “upper”, “lower”, “left”, and “right”, and the like, are used for representing a relative positional relationship, and when an absolute position of a described object is changed, the relative positional relationship may also be correspondingly changed. It may be understood that when an element such as a layer, a film, a region, or a substrate is described as being “on” or “under” another element, this element may be “directly” located “on” or “under” another element, or there may be an intermediate element.

In this disclosure, the word “comprising” or variations thereof, such as “comprising”, “including”, “having”, will be understood to include the stated element, integer or step, or combination of elements, integers or steps, but does not preclude the addition of other elements, integers or steps, or combination of elements, integers or steps.

“At least one of A, B and C” has the same meaning as “at least one of A, B or C” and includes the following combinations of A, B and C: A only, B only, C only, a combination of A and B, a combination of A and C, a combination of B and C, and a combination of A, B and C. “A and/or B” includes the following three combinations: A only, B only, and a combination of A and B.

In the descriptions of the present disclosure, “a plurality of” means two or more than two, unless otherwise specified.

In the present disclosure, the hydrocarbyl refers to hydrocarbyl that does not contain a heteroatom in the main structure, such as alkyl, alkenyl, alkynyl, cycloalkyl, cycloalkenyl, aryl and combinations thereof, and the hydrocarbyl may be substituted by a substituent selected from halogen, carboxyl, sulfonyl, hydroxyl, sulfhydryl, amino, nitro (—NO₂), cyano (—CN), alkyl, alkenyl, alkynyl, cycloalkyl, cycloalkenyl, aryl, alkyloxy, alkenoxy, alkynoxy, cycloalkoxy, cycloalkenoxy, aryloxy, heteroaryl, heterocyclyl and combinations thereof, but is not limited thereto.

In the present disclosure, a heterohydrocarbyl refers to a group obtained by substituting one or more carbons in the main structure of the hydrocarbyl as described above by a heteroatom group selected from, for example, but not limited to, O, S, N, B, P, Si, Se, C═O.

In the present disclosure, “C1-C6”, “C2-C6”, “C3-C6”, “C6-C10” and the like preceding a group refer to the number of carbon atoms contained in the group.

In the present disclosure, when no specific definition is otherwise provided, “hetero” means that at least one heteroatom selected from B, N, O, S, Se, Si, P, and the like is included in a functional group.

In this disclosure, “alkyl” may include a linear or branched alkyl. Unless otherwise defined, the alkyl may have 1 to 10 carbon atoms. In this disclosure, a numerical range such as “1 to 10” refers to various integers in a given range. For example, “1 to 10 carbon atoms” refers to alkyl that may contain 1 carbon atom, 2 carbon atoms, 3 carbon atoms, 4 carbon atoms, 5 carbon atoms, 6 carbon atoms, 7 carbon atoms, 8 carbon atoms, 9 carbon atoms or 10 carbon atoms. The alkyl may also be a lower alkyl having 1 to 6 carbon atoms. In addition, the alkyl may be substituted or unsubstituted. The unsubstituted alkyl can be “saturated alkyl group” without any double or triple bonds. Optionally, the alkyl is selected from alkyl having 1 to 6 carbon atoms including, but not limited to, methyl, ethyl, n-propyl, isopropyl, n-butyl, isobutyl, sec-butyl, tert-butyl, amyl and hexyl.

In the present disclosure, “alkenyl” may include a linear or branched alkenyl containing at least one carbon-carbon double bond. Unless otherwise defined, the alkenyl may have 2 to 10 carbon atoms. In this disclosure, a numerical range such as “2 to 10” refers to various integers in a given range. For example, “2 to 10 carbon atoms” refers to alkenyl that may contain 2 carbon atoms, 3 carbon atoms, 4 carbon atoms, 5 carbon atoms, 6 carbon atoms, 7 carbon atoms, 8 carbon atoms, 9 carbon atoms or 10 carbon atoms. The alkenyl may also be a lower alkenyl having 2 to 6 carbon atoms. In addition, the alkenyl group may be substituted or unsubstituted. Optionally, the alkenyl group is selected from alkenyl having 2-6 carbon atoms, including, but not limited to, vinyl, propen-1-yl, propen-2-yl, butenyl, pentenyl, hexenyl, and the like.

In the present disclosure, “alkynyl” may include a linear or branched alkynyl containing at least one carbon-carbon triple bond. Unless otherwise defined, the alkynyl may have 2 to 10 carbon atoms. In this disclosure, a numerical range such as “2 to 10” refers to various integers in a given range. For example, “2 to 10 carbon atoms” refers to alkynyl that may contain 2 carbon atoms, 3 carbon atoms, 4 carbon atoms, 5 carbon atoms, 6 carbon atoms, 7 carbon atoms, 8 carbon atoms, 9 carbon atoms or 10 carbon atoms. The alkynyl may also be a lower alkynyl having 2 to 6 carbon atoms. In addition, the alkynyl group may be substituted or unsubstituted. Optionally, the alkynyl is selected from alkynyl having 2-6 carbon atoms, including, but not limited to, ethynyl, propynyl, butyynyl, pentynyl, hexynyl, and the like.

In this disclosure, cycloalkyl refers to a group derived from a saturated cyclic carbon chain structure. Unless otherwise defined, the cycloalkyl may have 3 to 10 carbon atoms. In this disclosure, a numerical range such as “3 to 10” refers to various integers in a given range. For example, “3 to 10 carbon atoms” refers to cycloalkyl that may contain 3 carbon atoms, 4 carbon atoms, 5 carbon atoms, 6 carbon atoms, 7 carbon atoms, 8 carbon atoms, 9 carbon atoms or 10 carbon atoms. The cycloalkyl may be substituted or unsubstituted. Optionally, examples of the cycloalkyl may include but are not limited to cyclopentyl, cyclohexyl, and the like.

In this disclosure, aryl refers to an optional functional group or substituent derived from an aromatic carbocyclic ring. The aryl may be a monocyclic aryl group (e.g. phenyl) or a polycyclic aryl group. In other words, the aryl may be a monocyclic aryl group, a fused aryl group, two or more monocyclic aryl groups conjugated by carbon-carbon bonds, monocyclic aryl groups and fused aryl groups conjugated by carbon-carbon bonds, two or more fused aryl groups conjugated by carbon-carbon bonds. That is, unless otherwise specified, two or more aromatic groups conjugated by carbon-carbon bonds may also be considered as the aryl of the present disclosure. The aryl does not contain heteroatoms such as B, N, O, S, P, Se and Si. Examples of the aryl may include, but are not limited to, phenyl, naphthyl, and the like.

In the present disclosure, heteroaryl is a monovalent aromatic ring containing at least one heteroatom such as 1, 2, 3, 4 or 5 heteroatoms in a ring, the heteroatom may be selected from at least one of B, O, N, P, Si, Se and S. The heteroaryl may be a monocyclic heteroaryl group or a polycyclic heteroaryl group. In other words, the heteroaryl can be a single aromatic ring system or a plurality of aromatic ring systems linked by conjugation, and any one of the aromatic ring systems is an aromatic monocyclic ring or an aromatic fused ring. For example, the heteroaryl may include, but is not limited to, thienyl, furyl, pyrrolyl, imidazolyl, thiazolyl, oxazolyl, oxadiazolyl, triazolyl, pyridyl, bipyridyl, pyrimidinyl, triazinyl, acridyl, pyridazinyl, pyrazinyl, quinolinyl, and the like.

In the present disclosure, heterocyclyl is a monovalent non-aromatic ring containing at least one heteroatom such as 1, 2, 3, 4 or 5 heteroatoms in a ring, the heteroatom may be selected from at least one of B, O, N, P, Si, Se and S. The heterocyclyl may be monocyclic or polycyclic. For example, the heterocyclyl may include, but are not limited to, dihydropyridyl, piperidinyl, tetrahydrothienyl, 4-piperidonyl, pyrrolidinyl, 2-pyrrolidonyl, pyrrolinyl, tetrahydrofuranyl, tetrahydropyranyl, acridinyl, pyrimidinyl, imidazolidinyl, imidazolinyl, pyrazolidinyl, pyrazolinyl, piperazinyl, morpholinyl, oxazolidinyl, and the like.

In order to keep following description of the embodiments of the present disclosure clear and concise, detailed description of known functions and known components are omitted in the present disclosure.

### 1. Quantum Dot Ink

An embodiment of the present disclosure provides a quantum dot ink including:(1) a quantum dot material; (2) a cross-linking agent; and (3) a photoacid generator.

In the quantum dot ink of embodiments of the present disclosure, a weight ratio of the quantum dot material, the cross-linking agent and the photoacid generator may be 100:(1-30):(0.1-10), optionally 100:(2-10):(1-10), for example, 100:5:1, 100:10:1, 100:20:1, 100:30:1, 100:30:1, 100:5:2, 100:10:2, 100:20:2, 100:30:2, 100:5:3, 100:10:3, 100:20:3, 100:30:3, 100:5:4, 100:10:4, 100:20:4, 100:30:4, 100:5:5, 100:10:5, 100:20:5, 100:30:5. In these ranges, quantum dots having colloidal stability can be achieved, which is beneficial to the effect of forming a uniform thin film obtained by subsequent solution processing, and can achieve better photolithography patterning effect.

### (1) Quantum Dot Material

The quantum dot material includes quantum dots and an organic ligand on the surfaces of the quantum dots, and the organic ligand includes a cross-linking unit and a coordination functional group coordinated with the quantum dots.

In an embodiment, the organic ligand is soluble in water.

In an embodiment, the cross-linking unit of the organic ligand has a structure represented by the following formula I:

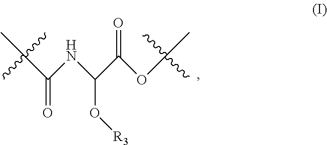

wherein, R₃ is a leaving group and may, for example, be selected from substituted or unsubstituted C1-C6 alkyl, substituted or unsubstituted C3-C6 cycloalkyl. The substituted substituent may be selected from halogen, C6-C8 aryl (e.g., phenyl, tolyl, xylene, and ethylphenyl), and in particular, R₃ can be selected from C1-C₄ alkyl, or benzyl.

In an embodiment, the coordination functional group contained in the organic ligand may be selected from carboxyl (—COOH), sulfonyl (—SO₃H), hydroxyl (—OH), sulfhydryl (—SH), amino (—NH₂), but is not limited thereto. In addition, the organic ligand may include one or more coordination functional groups, for example, 1, 2, or 3 coordination functional groups, and the coordination functional groups are each independently selected from the above groups.

In an embodiment, the organic ligand has a structure represented by the following formula II:

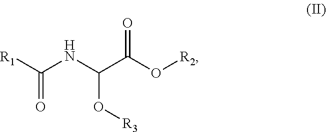

wherein, R₁ and R₂ are each independently selected from a linear, branched or cyclic saturated or unsaturated hydrocarbyl and heterohydrocarbyl, and at least one of R₁ and R₂ includes one or more coordination functional groups; and
R₃ is defined as described above.

In an embodiment, R₁ and R₂ may be each independently selected from a linear or branched C1-C6 alkyl substituted with one or more coordination functional groups, or one of R₁ and R₂ is a linear or branched C1-C6 alkyl substituted with one or more coordination functional groups, and the other one is selected from a linear or branched C1-C6 alkyl.

In an embodiment, R₁ and R₂ may be each independently selected from a linear or branched C1-C4 alkyl substituted with a coordination functional group selected from carboxyl (—COOH), sulfonyl (—SO₃H), hydroxyl (—OH), sulfhydryl (—SH), or amino (—NH₂), or one of R₁ and R₂ is selected from a linear or branched C1-C4 alkyl substituted with a coordination functional group selected from carboxyl (—COOH), sulfonyl (—SO₃H), hydroxyl (—OH), sulfhydryl (—SH), or amino (—NH)₂, and the other one is selected from a linear or branched C1-C4 alkyl.

In an embodiment, the organic ligand represented by the formula II may be selected from, for example:

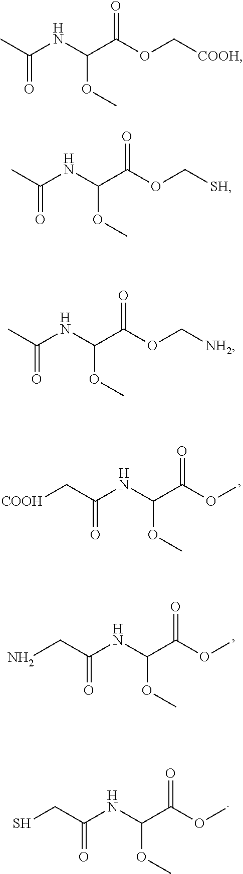

In an embodiment, the organic ligand has a structure represented by the following formula III:

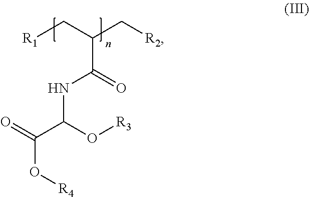

wherein, R₁, R₂ and R₄ are each independently selected from a linear, branched or cyclic saturated or unsaturated hydrocarbyl and heterohydrocarbyl, and at least one of R₁, R₂ and R₄ includes one or more coordination functional groups;
R₃ is defined as described above.

In formula III, n represents the number of the polymerized monomer unit, that is, polymerization degree.

In an embodiment, R₁, R₂ and R₄ may be each independently selected from a linear or branched C1-C6 alkyl substituted with one or more coordination functional groups; or two of R₁, R₂ and R₄ may be each independently selected from a linear, branched or cyclic C1-C6 alkyl substituted with one or more coordination functional groups, and another one is selected from a linear or branched C1-C6 alkyl, a linear or branched C2-C6 alkenyl, C3-C6 cycloalkyl, C3-C6 cycloalkenyl, C6-C10 aryl, or a group in which one or more carbons of the above groups are substituted with a group selected from O, S, N, or C═O; or one of R₁, R₂ and R₄ may be each independently selected from a linear, branched or cyclic C1-C6 alkyl substituted with one or more coordination functional groups, and another one is selected from a linear or branched C1-C6 alkyl, a linear or branched C2-C6 alkenyl, C3-C6 cycloalkyl, C3-C6 cycloalkenyl, C6-C10 aryl, or a group in which one or more carbons of the above groups are substituted with a group selected from O, S, N, or C═O.

In an embodiment, R₁, R₂ and R₄ may be each independently selected from a linear or branched C1-C4 alkyl substituted with the coordination functional group selected from carboxyl (—COOH), sulfonyl (—SO₃H), hydroxyl (—OH), sulfhydryl (—SH), or amino (—NH₂); or two of R₁, R₂ and R₄ may be each independently selected from a linear or branched C1-C4 alkyl substituted with the coordination functional group selected from carboxyl (—COOH), sulfonyl (—SO₃H), hydroxyl (—OH), sulfhydryl (—SH), or amino (—NH₂), and another one is selected from a linear or branched C1-C4 alkyl, a linear or branched C2-C4 alkenyl, C3-C6 cycloalkyl, C3-C6 cycloalkenyl, C6-C10 aryl, or a group in which one or more carbons of the above groups are substituted with a group selected from O, S, N, or C═O; or one of R₁, R₂ and R₄ is selected from a linear or branched C1-C4 alkyl substituted with the coordination functional group selected from carboxyl (—COOH), sulfonyl (—SO3H), hydroxyl (—OH), sulfhydryl (—SH), or amino (—NH₂), and another one is selected from a linear or branched C1-C4 alkyl, a linear or branched C2-C4 alkenyl, C3-C6 cycloalkyl, C3-C6 cycloalkenyl, C6-C10 aryl, or a group in which one or more carbons of the above groups are substituted with a group selected from O, S, N, or C═O.

The linear or branched C1-C4 alkyl substituted with the coordination functional group of carboxyl (—COOH), sulfonyl (—SO₃H), hydroxyl (—OH), sulfhydryl (—SH), or amino (—NH₂) may be, for example, carboxymethyl, carboxyethyl, carboxypropyl, carboxybutyl, sulfonylmethyl, sulfonylethyl, sulfonylpropyl, sulfonylbutyl, hydroxymethyl, hydroxyethyl, hydroxypropyl, hydroxybutyl, sulfhydrylmethyl, sulfhydrylethyl, sulfhydrylpropyl, sulfhydrylbutyl, aminomethyl, aminoethyl, aminopropyl, aminobutyl, and the like, but is not limited thereto. In an embodiment, the organic ligand represented by formula III may be selected from, for example:

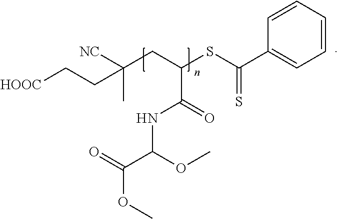

The quantum dot may be selected from: a Group II-VI quantum dot, such as CdS, CdSe, CdTe, ZnS, ZnSe, ZnTe, HgSe, HgTe, HgS, HgₓCd₁₋ₓTe, HgₓCd₁₋ₓS, HgₓCd₁₋ₓSe, HgₓZn₁₋ₓTe, CdₓZn₁₋ₓSe, or CdₓZn₁₋ₓS, wherein 0<x<1; or a Group III-V quantum dot, such as InP, InAs, InSb, GaAs, GaP, GaN, GaSb, InN, InSb, AlP, AlN, AlAs; or a Group IV-VI quantum dot, such as PbS, PbSe, PbTe; or a quantum dot with core-shell structure, including CdSe@ZnS, CdSe@CdS, InP@ZnS, CdTe@CdSe, CdSe@ZnTe, ZnTe@CdSe, ZnSe@CdS, or Cd₁₋ₓZnₓS@ZnS; or a ABX₃-type perovskite quantum dot, in which A is one or more of CH₃ NH₃⁺ (methylamine), NH₂CH═NH₂ (formamidine), and Cs⁺, and B is one or two of Pb²⁺ and Sn²⁺, X is one or more of Cl⁻, Br⁻, and I⁻, including CH₃NH₃PbBr₃, CH₃NH₃PbCl₃, CH₃ NH₃PbI₃, CsPbBr₃, CsPbCI₃, CsPbI₃; or other quantum dots, such as CuInS₂, CuInSe₂, and AgInS₂.

In the quantum dot material of the present disclosure, the weight ratio of the quantum dots to the organic ligand may be 100:(1-30), such as 100:1, 100:2, 100:3, 100:4, 100:5, 100:6, 100:7, 100:8, 100:9, 100:10, 100:11, 100:12, 100:13, 100:14, 100:15, 100:16, 100:17, 100:18, 100:19, 100:20, 100:21, 100:22, 100:23, 100:24, 100:25, 100:26, 100:27, 100:28, 100:29, 100:30, and optionally, may be 100:(2:10), such as 100:2, 100:3, 100:4, 100:5, 100:6, 100:7, 100:8, 100:9, 100:10, but is not limited thereto.

The quantum dot material of the present disclosure is not particularly limited in the manner in which it is obtained and may be prepared according to any suitable method in the art.

In an embodiment, for example, the quantum dot material of the present disclosure may be prepared by a ligand exchange method, the ligand exchange method includes:
(1) providing a first quantum dot material including quantum dots and a first ligand on the surfaces of the quantum dots; and
(2) performing a ligand exchange reaction between the first quantum dot material and a second ligand to obtain a second quantum dot material, wherein the second quantum dot material includes quantum dots and the second ligand on the surfaces of the quantum dots, and the second ligand is the ligand of the present disclosure as described above.

As the first quantum dot material, as long as the surfaces of the quantum dots are coated with an organic ligand, it can be applied.

For example, a first organic ligand may be organic acids (e.g., oleic acid), organic amines (e.g., oleamine), organophosphorous (e.g., trioctyl phosphine and trioctyl phosphine oxide), mercaptans (e.g., isooctyl mercaptan and sulfhydrylpropionic acid), polymers (polyvinylpyrrolidone), and the like.

### (2) Cross-Linking Agent

The cross-linking agent in the quantum dot ink in the present disclosure is used for a cross-linking reaction with an organic ligand in the quantum dot material when a quantum dot layer is exposed to the irradiation of ultraviolet light.

In an embodiment, a polyhydroxy compound is used as a cross-linking agent.

The polyhydroxy compound refers to a compound containing two or more hydroxyl groups in the molecule, which can also be called polyols.

In embodiments of the present disclosure, the polyhydroxy compound is selected from a compound having the following general formula IV:

R—(OH)ₘ (IV),
wherein, R is a m-valent group, which may be, for example, m-valent substituted or unsubstituted C1-C6 alkyl, substituted or unsubstituted C1-C6 alkoxyalkyl, substituted or unsubstituted C1-C6 alkylsulfanylalkyl, substituted or unsubstituted C3-C8 cycloalkyl, substituted or unsubstituted C₃-C₈ cycloalkenyl, substituted or unsubstituted C6-C10 aryl, substituted or unsubstituted 5 to 10-membered heteroaryl, substituted or unsubstituted 5 to 10-membered heterocyclyl, polyethylene glycol chain, polypropylene glycol chain and the like. The substituent may contain ester group, ether group, amido group, carbonyl group, and the like, but is not limited thereto,
m is an integer ≥2, for example, an integer of 2-4.

For example, when m=2, the molecule may be ethylene glycol, propylene glycol, butanediol (e.g., 1,4-butanediol); when m=3, the molecule can be glycerol; when m=4, the molecule can be pentaerythritol. The more the number of hydroxyl groups, the higher the cross-linking degree.

In embodiments of the present disclosure, the polyhydroxy compound may be selected from C2-C8 diol, C3-C8 triol, C4-C8 tetraol, polyethylene glycol, polypropylene glycol, and the like.

In embodiments of the present disclosure, the polyhydroxy compound may be selected from one or more of ethylene glycol, propylene glycol, butanediol, pentanediol, hexanediol, glycerol, pentaerythritol, pentaerythritol, polyethylene glycol and polypropylene glycol.

### (3) Photoacid Generator

The photoacid generator in the quantum dot ink in the present disclosure is used for releasing an acidic proton to catalyze the cross-linking reaction between the cross-linking agent and the organic ligand when the quantum dot layer is exposed under the irradiation of ultraviolet light.

In the present disclosure, there is no particular limitation on a suitable photoacid generator, as long as it can release an acidic proton when the quantum dot layer is exposed under the irradiation of ultraviolet light.

In embodiments of the present disclosure, for example, the suitable photoacid generator may be selected from: diazo salts, including but not limited to, diazo sulfate, diazo hydrochloride, diazo sulfonate, diazo hexafluorophosphate, diazo hexafluoroantimonate, diazo perchlorate and other small molecular diazo salts, as well as polymer diazo salts such as diphenylamine formaldehyde resins; organic polyhalides, including but not limited to, trichloroacetophenone, tribromomethyl phenyl sulfone, 4-phenoxydichloroacetophenone, triazine derivatives (such as 4,6-bis(trichloromethyl)-1,3,5 triazine derivatives); onium salts, including but not limited to, phosphonium salts, arsonium salts, selenonium salts, sulfonium salts (such as 2,4-dihydroxyphenyldimethylsulfonium trifluoromethane sulfonate) and iodonium salts; sulfonates, including but not limited to, N-p-toluenesulfonyloxy phthalimide, N-trifluoromethane sulfonyloxy succinimide, N-trifluoromethane sulfonyloxy naphthalene dicarboxyimide, dinitrobenzyl p-toluenesulfonate, p-toluenesulfonate of α-hydroxymethyl benzoin, and the like; and other classes of photoacid generators, including, but not limited to, α,α-bis(arylsulfonyl)diazomethane and α-carbacyl-α-sulfonyl diazomethane, and the like.

In addition, for ease of mixing and coating, the quantum dot ink of the embodiments of the present disclosure may also contain a solvent. The solvent may be selected from water or a water-miscible organic solvents, including but not limited to, lower alcohols (i.e., C1-C6 alkanols, including but not limited to, methanol, ethanol, n-propanol, isopropanol), ethers (tetrahydrofuran), acetone, and the like, optionally water, methanol, ethanol, tetrahydrofuran, acetone, and in particular, the solvent may be water or a mixture of water and the above organic solvents. In the mixture of water and the organic solvent, the volume content of water may be more than 1% to less than 100%, optionally 50-100%. In the range of amounts used, it can be dispersed stably in the mixed solvent in a colloidal solution state.

In an embodiment, the solvent in the quantum dot ink of the embodiment of the present disclosure is water.

In addition, the quantum dot ink of the embodiment of the present disclosure may also include an additive such as a thickener, but is not limited thereto. The content of the thickener can be adjusted according to the needs. For example, the thickener may be selected from methyl vinyl MQ silicone resin, polymethacrylate, or polycyanoacrylate. For example, the methyl vinyl MQ silicone resin is a stereostructure (nonlinear) long-chain spherical molecular structure with Si—O bond as the skeleton, which has high light transmittance and good film-forming performance. The thickener is added to the quantum dot layer, so that the quantum dot layer has good mechanical properties, high and low temperature resistance, electrical insulation, moisture resistance, waterproof and other excellent properties.

### 2. A Method for Patterning a Quantum Dot Layer

Another embodiment of the present disclosure relates to a method for patterning a quantum dot layer, the method includes the steps of:
a. forming a quantum dot layer with the quantum dot ink according to the present disclosure;
b. under the shielding of a mask, exposing the quantum dot layer under the irradiation of ultraviolet light to carry out a cross-linking reaction; and
c. removing the quantum dots in the unexposed region by eluting with a developing solution to obtain the patterned quantum dot layer.

In the embodiment of the present disclosure, the above steps a-c can be repeated a plurality of times as required. In some embodiments, panchromatic patterning of the red-green-blue quantum dot film layer can be achieved by repeating the above steps a-c.

### (a) Forming a Quantum Dot Layer

In step a, a thin film is formed with the quantum dot ink according to the present disclosure.

There is no particular limitation on the method for forming the thin film, and any suitable film forming method can be used, such as a spin coating method, a screen printing method, a scratch coating method, a drop coating method, a dip coating method, a Langmuir-Blodgett deposition film forming method, and the like.

### (b) Exposure

In an embodiment, a light intensity of the irradiation of ultraviolet light may be determined as required. For example, it may be 1-10000 mJ/cm². Optionally, the interval is 10-1000 mJ/cm², but is not limited thereto.

During the exposure process, under the excitation of ultraviolet light, a photoacid generator generates hydrogen ions, to activate the functional group of the cross-linking unit of the organic ligand which then undergoes a cross-linking reaction with the functional group in the cross-linking agent. Finally, the resulting product forms a network with the target molecules, thereby changing the solubility of the target molecules.

In an embodiment, the following reactions are carried out:

Firstly, the photoacid generator (PAG) generates hydrogen ions under the illumination

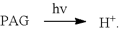

Then, under the action of H⁺, the polyhydroxy compound R—(OH)ₘ undergoes a cross-linking reaction with a cross-linking unit of the organic ligand represented by the formula I. For example, the cross-linking reaction is represented by the following equation, but is not limited thereto:

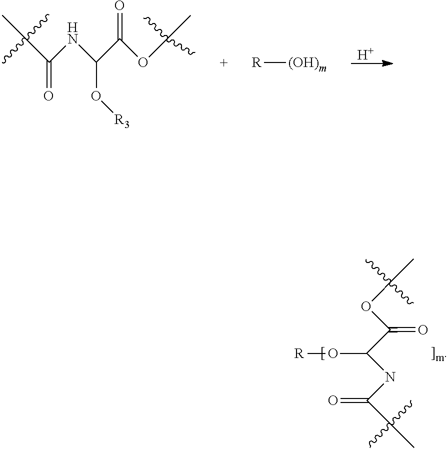

In addition, some hydroxyls in the polyhydroxy compound R—(OH)ₘ may not participate in the cross-linking reaction, for example, some cross-linking reaction products may be represented as follows:

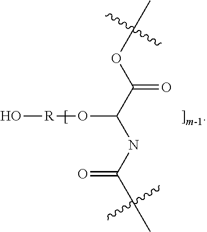

Other cross-linking reaction products may be contemplated by those skilled in the art.

In an embodiment, when carboxylic acid-terminated poly(methyl 2-acrylamido-2-methoxyacetate) is used as a quantum dot ligand, 1,4-butanediol is used as a cross-linking agent, and 2,4-dihydroxyphenyldimethylsulfonium trifluoromethane sulfonate is used as the photoacid generator, the following reactions are carried out:

Firstly, the photoacid generator 2,4-dihydroxyphenyldimethylsulfonium trifluoromethane sulfonate will undergo a hydrogen abstraction reaction with 1,2-butanediol containing active hydrogen under the illumination as follows:

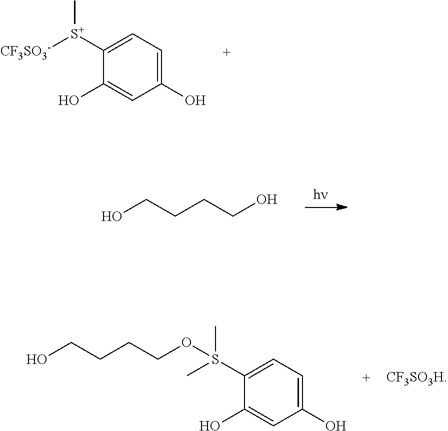

The generated trifluorosulfonic acid ionizes hydrogen ion H⁺:

CF₃SO₃H [symbol] CF₃SO₃⁻+H⁺.

The generated H⁺ enables a cross-linking reaction between the surface ligand of the quantum dot, poly(methyl 2-acrylamido-2-methoxyacetate) and 1,4-butanediol. The cross-linking reaction can be carried out between cross-linking units on different molecular chains or between cross-linking units on the same molecular chain. For example, the cross-linking reaction is represented by the following equation, but is not limited thereto:

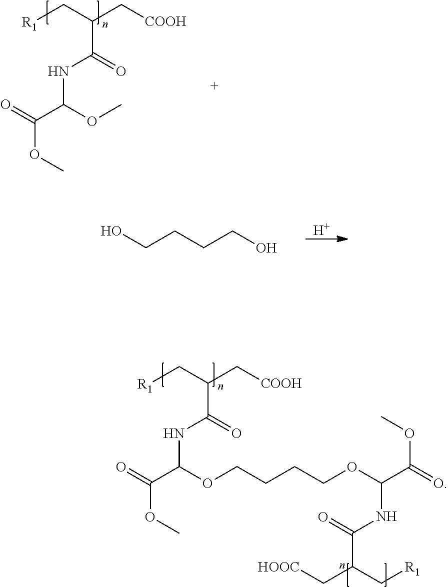

In an embodiment, when a carboxylic acid-terminated poly(methyl 2-acrylamido-2-methoxyacetate) with a polymerization degree n of 3 is used as a quantum dot ligand to undergo a cross-linking reaction with 1,4-butanediol, the cross-linking reaction may be represented by the following equation, but is not limited thereto:

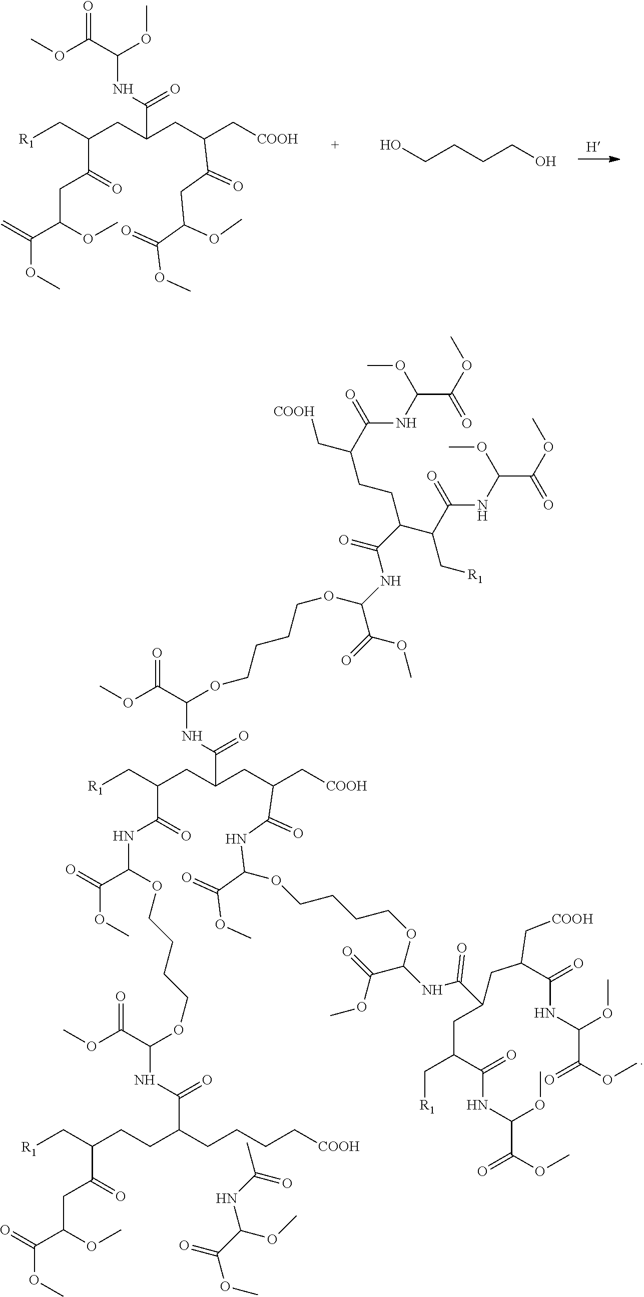

### (c) Development

In step c, the quantum dot layer exposed in step b is developed with a developing solution, and the quantum dots in the unexposed area are removed by eluting to obtain the patterned quantum dot layer.

The developing solution used can be selected according to the structure of the organic ligand used and the structure of the cross-linking product.

In an embodiment, the developing solution may be selected from water or a water-miscible solvent, including but not limited to, lower alcohols (i.e., C1-C6 alkanols, including but not limited to, methanol, ethanol, n-propanol, isopropanol, propenol), polyols (ethylene glycol, glycerol), lower aldehydes (formaldehyde, acetaldehyde, propionaldehyde), lower carboxylic acids (formic acid, acetic acid, propionic acid, n-butyric acid, n-valeric acid), ethers (tetrahydrofuran, diethylene glycol dimethyl ether and 1,4-epoxyhexane), acetone, N—N dimethylformamide, dimethyl sulfoxide, lower amines (ethylamine and ethylenediamine), pyridine, and the like; and optionally, is selected from water, methanol, ethanol, tetrahydrofuran, pyridine, acetone, N—N dimethylformamide, dimethyl sulfoxide, and the like. In particular, the solvent may be water or a mixture of water and the above-mentioned organic solvent. In the mixture of water and the organic solvent, the volume content of water may be more than 1% to less than 100%, optionally 50-100%.

In an embodiment, the developing solution is water.

The method for patterning a quantum dot layer according to an embodiment of the present disclosure may further include steps such as baking and vacuum drying as required, but is not limited thereto.

In the method for patterning a quantum dot layer, utilizing the machinable characteristic of a quantum dot solution, a polyhydroxy compound as a photocross-linking agent molecule is introduced, formulated to a novel quantum dot ink with a photoacid generator and a quantum dot material having a specific structural unit ligand, to form a quantum dot layer through a film-forming mode such as spin coating, and then exposed and developed, thereby directly realizing the patterning of the quantum dots. Because the photocross-linking agent molecule directly participates in the patterning of the quantum dot layer, compared with the existing photoresist patterning methods, there is no need to wash off the photoresist sacrificial layer, thereby greatly simplifying the process flow. For example, in order to construct the quantum dot layer, the existing indirect photoresist method requires 7 steps, while the disclosed method only requires 4 steps. In addition, because the ink system can be water-soluble and insoluble in water after the photocross-linking, water can be used as the developing solution, which is a green and environmentally friendly direct lithography patterning method.

### 3. Quantum Dot Layer

Another embodiment of the present disclosure relates to a quantum dot layer including a plurality of sub-pixels, a material for each sub-pixel includes a quantum dot material, a surface of the quantum dot material is linked with a cross-linking structure represented by the following formula V:

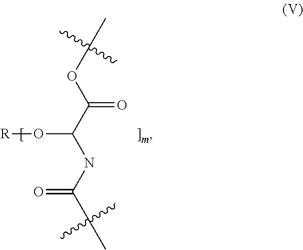

wherein, R and m are defined the same as those in general formula IV.

In an embodiment, the cross-linking structure linked with the surface of the quantum dot material is represented by formula V-1:

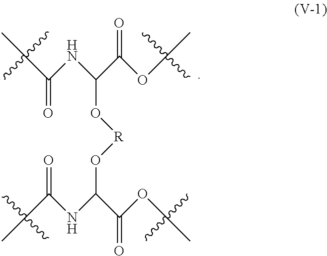

The definition of R is the same as those in general formula IV.

In an embodiment, the quantum dot layer of the present disclosure is prepared using the method for patterning the quantum dot layer of the present disclosure as described above.

### 4. Quantum Dot Optoelectronic Device

An embodiment of the disclosure further relates to a quantum dot optoelectronic device, including the quantum dot layer of the technical solutions as described above.

The quantum dot optoelectronic device may be a quantum dot light emitting diode, an optoelectronic detector, a photovoltaic solar cell, and the like, but is not limited thereto.

The quantum dot optoelectronic device may have the structure of a conventional optoelectronic device without particular limitation, except for the quantum dot layer according to the present disclosure.

In an embodiment, the quantum dot optoelectronic device may be a quantum dot light emitting diode. In addition to the quantum dot layer according to the present disclosure, the quantum dot light emitting diode may include, but is not limited to, a cathode, an anode, an electron injection layer, an electron transport layer, a hole transport layer, a hole injection layer, an ultraviolet light isolation layer, a pixel definition layer, a passivation layer, an encapsulation layer, and the like.

The structure, material composition and preparation method of the cathode, the anode, the electron injection layer, the electron transport layer, the hole transport layer, the hole injection layer, the ultraviolet light isolation layer, the pixel definition layer, the passivation layer, the encapsulation layer, and the like, of the quantum dot light emitting diode according to the embodiment of the present disclosure may adopt any suitable structure, material composition and preparation method without particular limitation. The present disclosure does not relate to improvements to these components and therefore these components are not described in detail to avoid obscuring the main technical ideas of the present disclosure.

The quantum dot light emitting diode according to the embodiment of the present disclosure may be provided as a single-side light-emitting type quantum dot device and a double-side light-emitting type quantum dot device, or as a top-light-emitting type, a bottom-light-emitting type and a double-side light-emitting type, as required.

### 5. Method for Fabricating the Quantum Dot Optoelectronic Device

An embodiment of the present disclosure further relates to a method for fabricating the quantum dot light emitting device, the method includes the step of forming a quantum dot layer by adopting the method for patterning the quantum dot layer.

The method for fabricating the quantum dot optoelectronic device may adopt conventional fabrication processes of optoelectronic devices without particular limitation, except for forming a quantum dot layer using the method for patterning the quantum dot layer according to the present disclosure. The present disclosure does not relate to improvements to processes other than the method for patterning the quantum dot layer and thus these processes are not described in detail to avoid obscuring the main technical ideas of the present disclosure.

### 6. Display Device

The embodiment of the present disclosure further relates to a display device, the display device includes the quantum dot light emitting diode according to the present disclosure.

In an embodiment, the display device may include a plurality of quantum dot light emitting diodes, at least one of which is a quantum dot light emitting diode according to the present disclosure. For example, the quantum dot light emitting diode in the display device may be a blue, green or red organic electroluminescent device, but is not limited thereto.

For example, other configurations in the display device can be with reference to the conventional designs. The display device may be any product or component with a display function, such as a mobile phone, a tablet computer, a television, a display, a notebook computer, a digital photo frame, a navigator, a vehicle-mounted display, a smart watch or a smart bracelet. Other essential components of the display device should be understood as being included in the display device by those of ordinary skill in the art, which will not be described herein in detail, and should not be regarded as a limitation on the present invention.

In order to further understand the present disclosure, the quantum dot ink, the method for patterning the quantum dot layer, and the quantum dot light emitting diode (QLED) of the present disclosure will be described in detail below in connection with Examples, and the scope of protection of the present disclosure is not limited by the following Examples.

The present disclosure provides a green and environment-friendly method for patterning quantum dots. The main principle is that hydrogen ions are generated by a photoacid generator, and the purpose of crosslinking quantum dots is achieved by catalyzing the cross-linking reaction (such as condensation reaction) between functional groups on the cross-linking agent (such as hydroxyls on the polyhydroxy compound) and functional groups on the quantum dot surface ligand. Then, the uncross-linked quantum dots are removed by the elution treatment with an appropriate developing solution, and the patterned quantum dot layer is finally obtained. On this basis, the inventor(s) developed a quantum dot ink suitable for the method, and prepared a quantum dot layer and a quantum dot optoelectronic device containing the quantum dot layer by using the method.

The method for patterning the quantum dot layer according to the embodiment of the present disclosure is a photoresist-free photopatterning method, which can avoid the problems of complex process, increased cost, poor solvent compatibility and the like caused by the traditional photoresist method. In addition, the construction of a multi-layer patterned quantum dot layer only needs repeated steps of spin coating, exposure and developing, which is easy to construct red, green and blue panchromatic multi-quantum dot layer patterned devices. In some embodiments according to the present disclosure, the polyhydroxy compound is used as the cross-linking agent to form a network molecule in the form of a covalent bond of a carbon-oxygen single bond, the covalent bond has strong action, and the cross-linking network structure is stable; moreover, the polyhydroxy compound is compatible with the solvent of the photoacid generator and the quantum dot material, and can be directly spin-coated, exposed and developed, thereby avoiding the glue removal step in the traditional lithography method, and the method is simple and reliable. In some embodiments according to the present disclosure, water can be used as the developing solution, the processing process is green and environmentally friendly, and there is a low cost advantage in mass production.

### Example 1: Synthesis of Water Soluble Polymer Poly(methyl 2-acrylamido-2-methoxyacetate) (PMAGME-COOH)

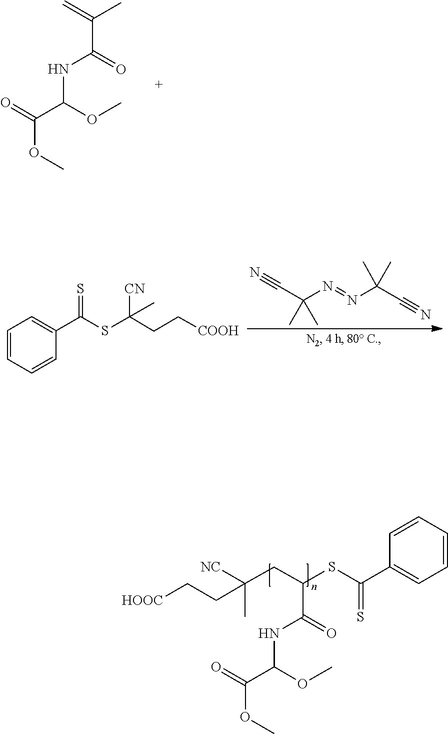

According to the method disclosed in reference Chem. Mater. 1997, 9, 1725, in a mixed solvent of 40 mL toluene and 30 mL n-butanol, 7 g methyl 2-acrylamido-2-methoxyacetate (MAGME) was used as a monomer, 0.03 g azobisisobutyronitrile (AIBN) was used as an initiator, 113 mg 4-cyano-4-(thiobenzoyl) valeric acid was used as a chain transfer reagent instead of carbon tetrabromide, poly(methyl 2-acrylamido-2-methoxyacetate) with carboxyl terminal group (PMAGME-COOH) was synthesized by reversible addition fragmentation.

### Example 2: Obtaining Water-Soluble Quantum Dots by Ligand Exchange

CdSe/ZnS red quantum dots with octyl mercaptan as the original ligand were selected and subjected to the ligand exchange with poly(methyl 2-acrylamido-2-methoxyacetate) with carboxyl terminal group (PMAGME-COOH) in water. The operation was as follows: 100 mg quantum dot powder was added into 2 mL aqueous solution dissolved with 0.1 g PMAGME-COOH, stirred at room temperature for 8 hours, and the quantum dots were gradually dispersed in the aqueous solution, the obtained solution was filtered with polyvinylidene fluoride membrane (PVDF), and the filtrate is quantum dots in which the solvent was water and the surface ligand was PMAGME-COOH.

### Example 3: Patterning of Quantum Dots

### Preparation of a Quantum Dot Ink

The water-soluble quantum dots in Example 2 were mixed with a cross-linking agent 1,4-butanediol and a photoacid generator 2,4-dihydroxyphenyl dimethylsulfonium trifluoromethane sulfonate, and the quantum dot ink, in which concentrations of the quantum dots, the cross-linking agent and the photoacid generator were respectively 20 mg/mL, 2 mg/mL and 0.4 mg/mL in the ink, was formulated according to a weight ratio of the quantum dots: the cross-linking agent: the photoacid generator of 100:10:1.

### Patterning of a Quantum Dot Layer

The previously prepared quantum dot ink was spin-coated on glass substrate to form a film, and was exposed to the irradiation of ultraviolet light under a mask, then washed off the uncross-linked quantum dots with water as a developing solution, and then baked at 100° C. to obtain the patterned quantum dot film layer.

### Example 4: Preparation of Inverted Bottom Emission Patterned QLED Device

On an indium tin oxide (ITO) substrate, zinc oxide nanoparticles were spin-coated in air by a sol-gel method (2000 rpm, 30 s, 75 mg/mL), and annealed at 180° C. for 1 minute. The quantum dot ink of Example 3 was then spin-coated (2000 rpm, 30 s). After that, it was placed under a photomask and exposed for 30 s with 10 mW/cm² 254 nm low-pressure mercury lamp, and then immersed in water for 2 minutes to develop, and annealed at 100° C. for 10 minutes, to obtain the patterned quantum dot film layer.

Then, a hole transport layer (N,N′-bis(1-naphthyl)-N,N′-diphenyl-1,1′-diphenyl-4,4′-diamine (NPB)) and a hole injection layer (MoO₃) were prepared by an evaporation equ ipment, and evaporated with silver electrode 120 nm. After encapsulating, the device was prepared.

### Example 5: Preparation of Upright Bottom Emission Patterned QLED Device

An ITO substrate was washed with deionized water and isopropanol, respectively, and then treated in plasma cleaner (violet plus ozone) for 15 minutes; and spin-coated with poly (3,4-ethylenedioxythiophene): polystyrene sulfonate (PEDOT: PSS) (2000 rpm, 30 s) in air and baked at 120° C. for 10 minutes to remove the water solvent. Then, the cross-linked poly[(9,9-dioctylfluoren-2,7-diyl)-co-(4,4′-N-(4-sec-butylphenyl)diphenylamine)](TFB) chlorobenzene solution was spin-coated in a glove box under nitrogen atmosphere (8 mg/mL, 2000 rpm, 30 s), and annealed at 150° C. for 30 minutes. The quantum dot ink of Example 3 was then spin-coated (2000 rpm, 30 s). After that, it was placed under a photomask and exposed with 10 mW/cm² 254 nm low-pressure mercury lamp for 30 seconds, and then immersed in water for 2 minutes to develop, and annealed at 100° C. for 10 minutes, to obtain the patterned quantum dot film layer.

Zinc oxide nanoparticles were then spin-coated in a glove box (30 mg/mL, 3000 rpm, 30 s), and then baked at 120° C. for 10 minutes to remove the solvent; and evaporated with the aluminum electrode 120 nm. Finally, the device was prepared after dispensing and encapsulating.

Although the present disclosure has been described as above, the contents described are for the sake of ease of understanding of the embodiments employed in the present disclosure only and are not intended to limit the present disclosure. Any person skilled in the art of the present disclosure may make any modification and change in forms and details of implementation without departing from the spirit and scope disclosed in the present disclosure. However, the scope of patent protection of the present disclosure is still subject to the scope defined in the appended claims.

1. A quantum dot ink, comprising a quantum dot material, a cross-linking agent, and a photoacid generator;
wherein, the quantum dot material comprises quantum dots and an organic ligand on surfaces of the quantum dots, and the organic ligand comprises a cross-linking unit and a coordination functional group coordinated with the quantum dots;
the cross-linking unit of the organic ligand has a structure represented by the following formula I: 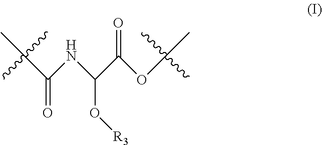
wherein, R₃ is a leaving group,
the cross-linking agent is a polyhydroxy compound represented by the following general formula IV:
R—(OH)m (IV),
wherein, R is a m-valent group,
m is an integer ≥2.

2. The quantum dot ink according to claim 1, wherein, R₃ is selected from substituted or unsubstituted C1-C6 alkyl, or substituted or unsubstituted C3-C6 cycloalkyl.

3. The quantum dot ink according to claim 1, wherein, R₃ is selected from C1-C4 alkyl, or benzyl.

4. The quantum dot ink according to claim 1, wherein, the organic ligand has a structure represented by the following formula II: 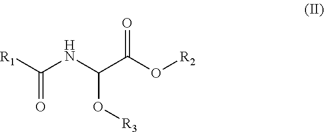
wherein,
R₁ and R₂ are each independently selected from a linear, branched or cyclic saturated or unsaturated hydrocarbyl and heterohydrocarbyl, and at least one of R₁ and R₂ comprises one or more coordination functional groups; and
R₃ is defined as the formula I.

5. The quantum dot ink according to claim 1, wherein, the organic ligand has a structure represented by the following formula III: 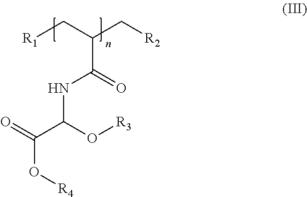
wherein,
R₁, R₂ and R₄ are each independently selected from a linear, branched or cyclic saturated or unsaturated hydrocarbyl and heterohydrocarbyl, and at least one of R₁, R₂ and R₄ comprises one or more coordination functional groups;
R₃ is defined as the formula I.

6. The quantum dot ink according to claim 1, wherein, a weight ratio of the quantum dots to the organic ligand in the quantum dot material is 100:(1-30).

7. The quantum dot ink according to claim 1, wherein, R is selected from m-valent substituted or unsubstituted C1-C6 alkyl, substituted or unsubstituted C1-C6 alkoxyalkyl, substituted or unsubstituted C1-C6 alkylsulfanylalkyl, substituted or unsubstituted C3-C8 cycloalkyl, substituted or unsubstituted C3-C8 cycloalkenyl, substituted or unsubstituted C6-C10 aryl, substituted or unsubstituted 5 to 10-membered heteroaryl, substituted or unsubstituted 5 to 10-membered heterocyclyl, polyethylene glycol chain, or polypropylene glycol,
m is an integer from 2 to 4.

8. The quantum dot ink according to claim 1, wherein, the polyhydroxy compound is selected from C2-C8 diol, C3-C8 triol, C4-C8 tetraol, polyethylene glycol, or polypropylene glycol.

9. The quantum dot ink according to claim 1, wherein, the polyhydroxy compound is selected from ethylene glycol, propylene glycol, butanediol, pentanediol, hexanediol, glycerol, pentaerythritol, pentaerythritol, polyethylene glycol, or polypropylene glycol.

10. The quantum dot ink according to claim 1, wherein, a weight ratio of the quantum dot material, the cross-linking agent, and the photoacid generator is 100:(1-30):(0.1-10).

11. The quantum dot ink according to claim 1, further comprising a solvent.

12. The quantum dot ink according to claim 11, wherein, the solvent is water.

13. A method for patterning a quantum dot layer, wherein, the method comprises the steps of:
a. forming a quantum dot layer with the quantum dot ink according to claim 1;
b. under the shielding of a mask, exposing the quantum dot layer under the irradiation of ultraviolet light to carry out a cross-linking reaction; and
c. removing the quantum dots in the unexposed region by eluting with a developing solution to obtain the patterned quantum dot layer.

14. The method for patterning a quantum dot layer according to claim 13, wherein, the developing solution is selected from water, or a solvent miscible with water.

15. The method for patterning a quantum dot layer according to claim 13, wherein, the developing solution is water.

16. The method for patterning a quantum dot layer according to claim 13, wherein, the steps a-c are repeated a plurality of times.

17. A quantum dot layer, comprising a plurality of sub-pixels, wherein, a material for each sub-pixel comprises a quantum dot material, and a surface of the quantum dot material is linked with a cross-linking structure represented by the following formula V: 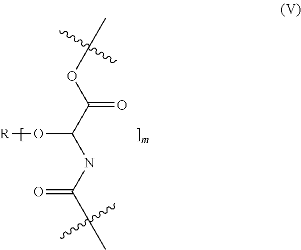
wherein, R is selected from m-valent substituted or unsubstituted C1-C6 alkyl, substituted or unsubstituted C1-C6 alkoxyalkyl, substituted or unsubstituted C1-C6 alkylsulfanylalkyl, substituted or unsubstituted C3-C8 cycloalkyl, substituted or unsubstituted C3-C8 cycloalkenyl, substituted or unsubstituted C6-C10 aryl, substituted or unsubstituted 5 to 10-membered heteroaryl, substituted or unsubstituted 5 to 10-membered heterocyclyl, polyethylene glycol chain, or polypropylene glycol, and
m is an integer from 2 to 4.

18. The quantum dot layer according to claim 17, wherein, the cross-linking structure linked with the surface of the quantum dot material is represented by formula V-1:

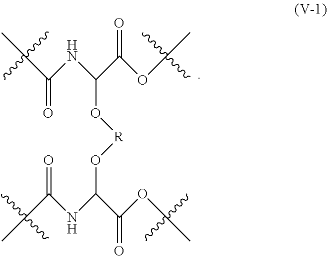

19. A quantum dot optoelectronic device, comprising the quantum dot layer according to claim 17.

20. A display device, comprising a quantum dot light emitting diode, wherein, the quantum dot light emitting diode comprises the quantum dot layer according to claim 17.
